(19) United States
(12) Patent Application Publication
(10) Pub. No.: US 2026/0302580 A1
(43) Pub. Date: Oct. 1, 2026

(54) WAVEGUIDES AND FABRICATION THEREOF

(71) Applicant: Jones Microwave Inc, Edmonton (CA)

(72) Inventors: Thomas R. Jones, Edmonton (CA); Dimitrios Peroulis, West Lafayette, IN (US); Douglas W. Barlage, Edmonton (CA)

(73) Assignee: Jones Microwave Inc, Edmonton (CA)

(21) Appl. No.: 19/096,533

(22) Filed: Mar. 31, 2025

(51) Int. Cl. H01P 1/15; H01L 23/66; H01P 3/12

(52) U.S. Cl. CPC H01P 1/15; H01P 3/121; H10W 44/20; H10W 44/216; H10W 44/259

(57) ABSTRACT

Provided are photoconductive solid-state evanescent-mode waveguide switches, and methods of fabricating and assembling the same. A radio frequency (RF) switch may be configured to switch between impeded and non-impeded states of RF transmission through the switch. Such switches have a high surface area semiconductor protrusion or discrete obstacle within the switch, which provides increased switching speeds between the impeded and non-impeded states.

### BACKGROUND

A radio frequency (RF) switch may be used to impede RF signals within the switch.

### SUMMARY

According to aspects of the disclosure, there is provided a radio frequency (RF) switch integrated with a semiconductor substrate, the RF switch comprising: a waveguide channel disposed in the semiconductor substrate, the waveguide channel comprising at least one internal wall; a semiconductor protrusion extending from the at least one internal wall into the waveguide channel, wherein the semiconductor protrusion comprises a surface configured to receive electromagnetic radiation (EMR); and at least one trench extending into the surface of the semiconductor protrusion.

In some embodiments, the semiconductor protrusion is configured to receive, in the at least one trench, the EMR from an EMR emitter coupled to the surface; and responsive to receiving the EMR, the semiconductor protrusion is configured to impede RF signals in the waveguide channel.

In some embodiments, the at least one internal wall is formed of the semiconductor substrate; and the waveguide channel comprises: a metallic layer formed on the at least one internal wall; and at least one port configured to transmit RF signals into and/or out of the waveguide channel.

In some embodiments, the EMR emitter comprises a laser diode, a vertical-cavity-surface-emitting laser (VCSEL), a light emitting diode (LED), or an optical fiber.

In some embodiments, the RF switch further comprises: an anti-reflective layer disposed on the surface.

In some embodiments, the RF switch further comprises: a reflective layer disposed on at least a portion of the semiconductor protrusion.

In some embodiments, the RF switch further comprises: an aperture exposing the surface of the semiconductor protrusion.

In some embodiments, the aperture has a first etch depth; and the at least one trench has a second etch depth.

In some embodiments, the semiconductor protrusion comprises a first end and a second end opposite the first end; the first end of the semiconductor protrusion extends into the waveguide channel; and the at least one trench extends into the surface of the semiconductor substrate at the second end of the semiconductor protrusion.

In some embodiments, the RF switch comprises a plurality of semiconductor protrusions extending from the at least one internal wall into the waveguide channel.

According to aspects of the disclosure, there is provided a radio frequency (RF) switch integrated with a semiconductor substrate, the RF switch comprising: a waveguide channel disposed in the semiconductor substrate; a discrete semiconductor obstacle disposed in the waveguide channel, wherein the discrete semiconductor obstacle comprises a surface configured to receive electromagnetic radiation (EMR); and at least one trench extending into the surface of the discrete semiconductor obstacle.

In some embodiments, the discrete semiconductor obstacle is configured to receive, in the at least one trench, the EMR from an EMR emitter coupled to the surface; and responsive to receiving the EMR, the discrete semiconductor obstacle is configured to impede RF signals in the waveguide channel.

In some embodiments, the waveguide channel comprises: at least one internal wall; a metallic layer formed on the at least one internal wall; and at least one port configured to transmit RF signals into and/or out of the waveguide channel.

In some embodiments, the discrete semiconductor obstacle comprises silicon.

In some embodiments, the discrete semiconductor obstacle comprises a III-V semiconductor material.

In some embodiments, the discrete semiconductor obstacle comprises germanium and/or silicon germanium.

In some embodiments, the at least one trench comprises a plurality of trenches.

According to aspects of the disclosure, there is provided a radio frequency (RF) switch integrated with a semiconductor substrate, the RF switch comprising: a first port arranged in the semiconductor substrate; a second port arranged in the semiconductor substrate; and means for selectively impeding transmission of RF signals between the first port and the second port, the means comprising at least one trench.

In some embodiments, the RF switch further comprises: a waveguide channel extending between the first port and the second port, wherein the means is arranged in the waveguide channel.

In some embodiments, the means is configured to, responsive to receiving EMR at the trench, impede RF signals between the first port and the second port.

### BRIEF DESCRIPTION OF DRAWINGS

Various aspects and embodiments of the technology will be described with reference to the following figures. It should be appreciated that the figures are not necessarily drawn to scale. Items appearing in multiple figures are indicated by the same reference number in all the figures in which they appear.

FIGS. 1A-1B show perspective views of a radio frequency (RF) switch, according to some embodiments;

FIG. 2 shows an exploded cross-sectional view of an RF switch, according to some embodiments;

FIGS. 3A-3F shows a cross-sectional view of a process flow of manufacturing components of an RF switch, according to some embodiments;

FIGS. 4A-4F shows a cross-sectional view of a process flow of manufacturing components of an RF switch, according to some embodiments;

FIG. 5 shows an exploded cross-sectional view of an RF switch, according to some embodiments;

FIGS. 6A-6C show perspective views of components of an RF switch, according to some embodiments;

FIGS. 7A-7B show perspective views of components of an RF switch, according to some embodiments;

FIGS. 8A-8B show perspective views of components of an RF switch, according to some embodiments;

FIGS. 9A-9C show perspective views of components of an RF switch, according to some embodiments;

FIGS. 10A-10B show perspective views of an RF switch system, according to some embodiments;

FIGS. 11A-11C show perspective views of a process of assembling an RF switch system, according to some embodiments;

FIGS. 12A-12B show perspective views of an RF switch system, according to some embodiments;

FIG. 13A-13G shows a cross-sectional view of a process flow of manufacturing components of an RF switch, according to some embodiments;

FIG. 14 shows an exploded cross-sectional view of an RF switch, according to some embodiments;

FIG. 15 shows an exploded cross-sectional view of an RF switch, according to some embodiments;

FIG. 16 shows a perspective view of components of an RF switch, according to some embodiments;

FIG. 17 shows a cross-sectional view of components of an RF switch, according to some embodiments;

FIG. 18 shows a cross-sectional view of components of an RF switch, according to some embodiments;

FIGS. 19A-19B shows a cross-sectional view of operation of an RF switch, according to some embodiments;

FIG. 20 shows a schematic block diagram of an RF switch system, according to some embodiments; and

FIG. 21 shows an exemplary block diagram of a special purpose computer system that can be improved over conventional implementations based on implementations and/or execution of methods discussed herein.

### DETAILED DESCRIPTION

### 1. Introduction

Aspects of the disclosure relate to photoconductive solid-state evanescent-mode waveguide switches, and methods of fabricating and assembling the same. According to aspects of the disclosure, there may be provided a radio frequency (RF) switch for switching between impeded and non-impeded states of RF transmission through the switch. Switches according to aspects of the disclosure may provide increased switching speeds between the impeded and non-impeded states by having a high surface area semiconductor protrusion or discrete obstacle within the switch.

In some embodiments, the RF switch comprises a waveguide channel disposed in the semiconductor substrate, which may comprise at least one internal wall. The switch may further comprise a semiconductor protrusion extending from the at least one internal wall into the waveguide channel, or a discrete semiconductor obstacle disposed in the waveguide channel, or a plurality of one of these semiconductor structures. Further, the switch may comprise an aperture exposing a surface of the semiconductor protrusion or a surface of the discrete semiconductor obstacle, and the aperture may be configured to transmit electromagnetic radiation (EMR) to the semiconductor protrusion or the discrete semiconductor obstacle.

The semiconductor protrusion or the discrete semiconductor obstacle may have at least one increased surface area structure, e.g., an opening such as a trench, extending into a surface thereof. In other embodiments, the increased surface area structure may include structures other than openings, such as protrusions. An opening or other structure may increase the surface area of the semiconductor structures. The increased surface area may allow faster switching speed through increased surface recombination centers for decreased carrier lifetime, and through providing thinner semiconductor regions with higher photoconductivity for deep absorption of photons. Therefore, the higher surface area may further provide for the use of alternative semiconductor materials with faster free-carrier mobilities than silicon, such III-V semiconductor materials, including gallium arsenide (GaAs). As such, the RF switch may be integrated with a semiconductor substrate, such as a silicon or III-V semiconductor material (e.g., Gallium arsenide GaAs).

During operation, the semiconductor protrusion or discrete semiconductor obstacle may receive EMR (such as light) at its at least one opening or trench from an EMR emitter coupled to the aperture (such as a laser diode, a vertical-cavity-surface-emitting laser (VCSEL), a light emitting diode (LED), or an optical fiber, where such optical fiber may in turn be coupled to another EMR emitter). In response to receiving the EMR, the semiconductor protrusion or discrete semiconductor obstacle may be configured to impede RF signals in the waveguide channel, such as by switching from a non-impeding state to an impeding state. Responsive to the EMR no longer being emitted, the semiconductor protrusion or discrete semiconductor obstacle may be configured to reduce the impedance of RF signals, such as by switching from the impeding state back to the non-impeding state.

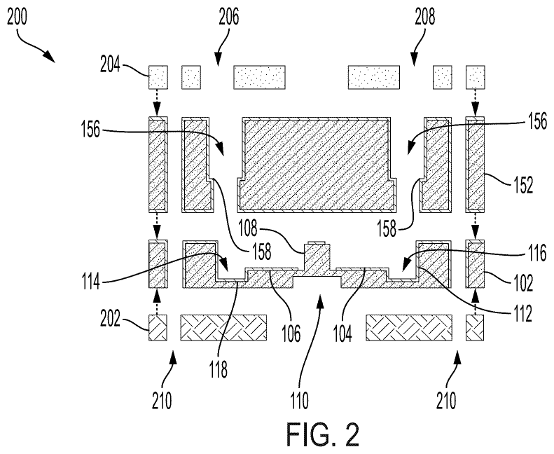

FIG. 2 shows an exploded cross-sectional view of an RF switch, according to some embodiments. FIG. 2 is illustrative of a general arrangement of RF switches, and variations of the arrangement described with respect to FIG. 2 are discussed throughout the application. RF switch 200 is integrated with a semiconductor substrate 102. A waveguide channel 104 is disposed in the semiconductor substrate 102, and the waveguide channel comprises at least one internal wall 106. A semiconductor protrusion 108 extends from the at least one internal wall 106 into the waveguide channel 104. An aperture 110 exposes a surface of the semiconductor protrusion 108 and the aperture is configured to transmit electromagnetic radiation (EMR) to the semiconductor protrusion 108. The waveguide channel further comprises at least one sidewall 112, and may also include at least one opening, such as trenches 118.

The RF switch 100 further comprises a first port 114 and a second port 116, which may each be configured to transmit RF signals into and/or out of the waveguide channel 104. The semiconductor protrusion 108 is configured to receive the EMR from an EMR emitter coupled to the aperture 110. Responsive to receiving the EMR, the semiconductor protrusion 108 is configured to impede RF signals in the waveguide channel 104, such as RF signals between the first port 114 and the second port 116.

The RF switch 200 may be a stacked assembly of the semiconductor substrate 102, a semiconductor substrate 152, and flanges 202 and 204. Fastener alignment holes 210 may extend through each component in the stack.

Semiconductor substrate 152 may include channels 156 extending from RF input/outputs to the waveguide channel 104. The channels 156 may include steps 158 which provide different portions of the channels 156 with different dimensions (e.g., width).

Flange 202 may be a custom flange piece. Flange 202 may include a corresponding opening for aperture 110 providing an optics feed. Flange 204 may be a standard waveguide flange. Flange 204 may include a first flange RF input/output 206, and a second flange RF input/output 208.

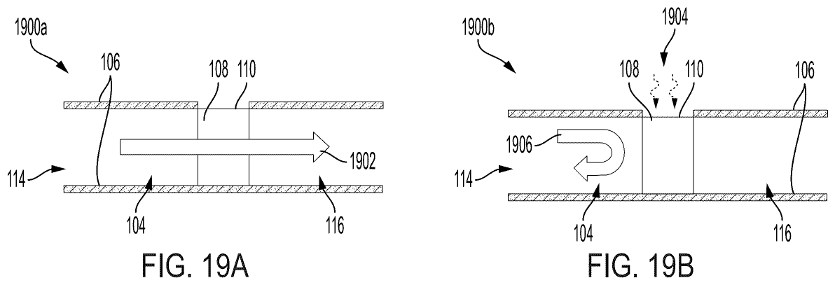

FIGS. 19A-19B shows a cross-sectional view of operation of RF switches, according to some embodiments. FIG. 19A shows a transmission state 1900a (ON state) of the switch and FIG. 19B shows a non-transmission state 1900b (OFF state) of the switch. In the transmission state 1900a, no EMR is applied to the semiconductor protrusion 108, and signals 1902 (e.g., RF waves) are transmitted through the waveguide channel 104 between ports 114 and 116. In the non-transmission state 1900b, EMR 1904 is applied to the semiconductor protrusion 108, generating photo-exciting semiconductor (e.g., silicon) plasma, and signals 1906 (e.g., RF waves) are not transmitted through the waveguide channel 104 between ports 114 and 116.

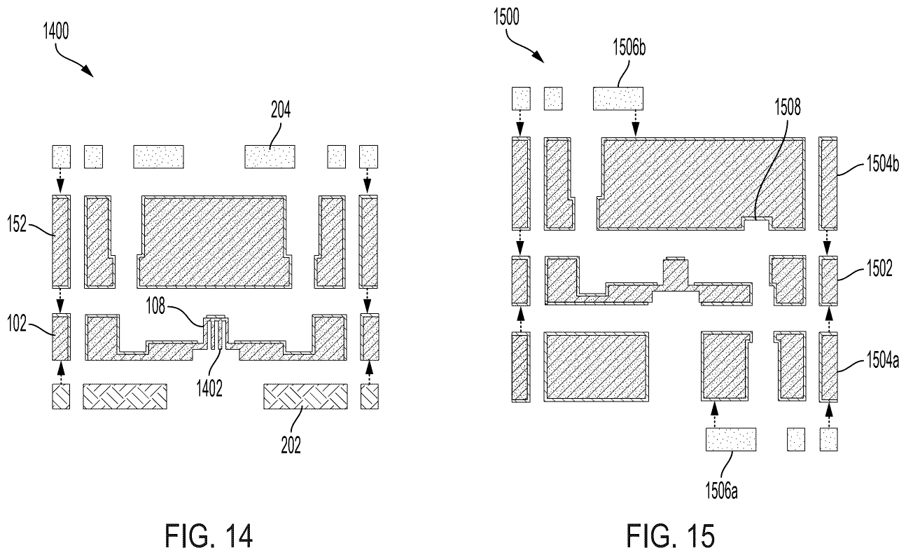

FIG. 14 shows one embodiment of an RF switch 1400 with increased speed switching. RF switch 1400 may be configured similarly as RF switch 2 described above with respect to FIG. 2, except as described herein. RF switch 1400 is integrated with a semiconductor substrate 102. A waveguide channel is disposed in the semiconductor substrate 102, and the waveguide channel comprises at least one internal wall. A semiconductor protrusion 108 has a first end extending from the at least one internal wall into the waveguide channel. An aperture exposes a surface of the semiconductor protrusion 108 and the aperture is configured to transmit electromagnetic radiation (EMR) to the semiconductor protrusion 108. At least one opening, such as trench 1402, extends into the surface of the semiconductor protrusion 108 at a second end of the semiconductor protrusion 108. The at least one trench 1402 may provide high surface area of the semiconductor protrusion 108, which may provide increased speed switching, as discussed throughout the disclosure. In RF switch 1400. the semiconductor protrusion 108 is configured to receive, in the at least one trench 1402, the EMR from an EMR emitter coupled to the aperture 110, which may increase switching speed.

The disclosure provides for the fabrication and assembly of a photoconductive solid-state evanescent-mode (EVA) waveguide switch.

The disclosure is organized as follows:
Section 2—A description of the general operation and assembly of certain embodiments of switch technology is provided.
Section 3—A description of the fabrication process according to some embodiments is presented, including processes and equipment used.
Section 4—Details of the fabrication of an example switch according to some embodiments are presented, along with methods of fabricating, aligning, bonding, and assembling the structure for improved performance, yield, and/or integration, according to some embodiments.
Section 5—Fabrication results of certain embodiments of the switch are discussed, and improvements to processes are presented for improved results and performance.
Section 6—Assembly of switch components according to some embodiments is presented using multi-wafer stacking and mechanical bonding.
Section 7—Some embodiments of a switch and associated fabrication processes with increased speed of ON-to-OFF and OFF-to-ON state transitions are described.
Section 8—An assembly according to some embodiments of the switch using an inline approach with axial waveguide flanges for improved insertion losses in the ON state of the switch is described.
Section 9—An overview of further variations, according to some embodiments.
Section 10—An overview of arrangements of systems incorporating RF switches, according to some embodiments.
Section 11—Incorporation by Reference

### 2. Structure

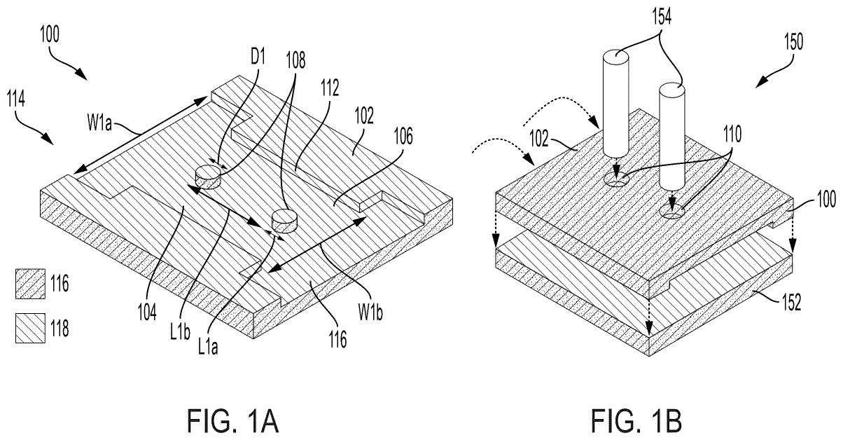

FIGS. 1A-1B show perspective views of a radio frequency (RF) switch, according to some embodiments. In FIGS. 1A-1B, a 3D layout of an EVA waveguide switch 100 is provided to demonstrate a particular embodiment of the design. Two semiconductor protrusions 108, here, as silicon posts, are located and centered within an EVA region of a low-profile, air-filled, silicon micromachined waveguide channel 104, having width W1b and at least one internal wall 106 and at least one sidewall 112 (e.g., a Top Wafer or Device Wafer) in the semiconductor substrate 102. The posts may have diameter D1 and a height, and may be separated by length L1b. Bulk dielectric and conductive properties of the silicon posts may be controlled by optical excitation from the back side of the wafer. The switch can be turned into an OFF state, reflecting RF energy, by applying light with optical energy (E_{g}) greater than the semiconductor material of the posts (for silicon, E_{g}=1.12 eV). With no light applied, the switch is in an ON state, where the shunt dielectric post along with the effective shunt inductance formed by the EVA waveguide region operating below its cutoff frequency combine to make a resonator. Two resonators are inductively coupled, forming a bandpass filter response for low loss transmission of RF energy from first port 1 114 to second port 116 (or vice-versa), having width W1a. The posts may be located length L1a into the channel 104 The Device Wafer may be flipped and bonded onto a second semiconductor substrate 152 or wafer to form the complete waveguide channel. The substrate 102 may comprise apertures 110 for optical fibers 154 This second wafer (e.g., a Bottom Wafer or Transition Wafer) can include an etched-out region within the wafer that provides connection to standard waveguide flanges [4] or to various semiconductor platforms including CMOS (complementary metal-oxide semiconductor). The materials illustrated in FIGS. 1A and 1B may include a semiconductor material 120 (such as silicon) and a metal 122 (such as copper).

In FIG. 2, a cross-section (exploded view) of an assembled embodiment of a silicon micromachined photoconductive solid-state EVA waveguide switch is shown. The Device Wafer and the Transition Wafer are stacked between standard flange RF input/output metal machined waveguide connectors on one side, and a custom metal machined flange piece on the other. For this embodiment, the flange piece may be made from stainless steel cut with a CO₂ laser system. Openings may be etched away for screw holes, alignment holes, and a hole for the fiber optics to be placed into the back side of the Device Wafer to control the switch operation. Standard machine screws may be used to mechanically bond the pieces together. Different types of bonding, including thermocompression bonding, may also be used to attach the pieces together for switches with improved RF performance, yield, or integration compatibility, as discussed in Section 4.2. Furthermore, instead of having both waveguide flanges on one side, an inline design may also be realized with improved performance, discussed in more detail in Section 8.

FIGS. 1A-1B show a 3D layout of a photoconductive EVA waveguide switch (units in μm) [2]. FIG. 1A shows a Top wafer (Device Wafer) showing the EVA section and photoconductive silicon posts in a silicon micromachined waveguide. For this embodiment, which may be designed for operation in W-band (75-110 GHz), the main width of the waveguide is 2540 μm, with a post height of 100 μm. The remaining dimensions may be: W eva=1740 μm, Lcp=1370 μm, Lin=465 μm, Dsi=320 μm. FIG. 1B shows the top wafer flipped on top of the bottom wafer for bonding, with fibers inserted into holes on the back side of the top wafer to optically excite the silicon posts and generate photoconductivity. The bottom wafer may also include an etched transition structure within its wafer (Transition Wafer) to connect the EVA waveguide etched in the top wafer to standard waveguide flanges, shown in FIG. 2.

FIG. 2. Shows a cross-section showing the assembly (exploded view) of a silicon micromachined photoconductive solid-state EVA waveguide switch including connection to standard waveguide flanges. An etched region within the Transition Wafer is included to provide this connection.

### 3. Process Flow

According to some embodiments, the structure for a photoconductive solid-state EVA waveguide switch consists of three pieces, as shown in FIG. 2: (i) a silicon wafer forming the Device Wafer (Wafer 1); (ii) a silicon wafer forming the Transition Wafer (Wafer 2); and (iii) a flange (which may be laser-cut stainless-steel) providing a mechanically secure structure to allow connection of standard waveguide flanges to the device using screws.

These pieces may be stacked, bonded, and connected to standard waveguide flanges as the input/output of the RF signal into and out of the switch.

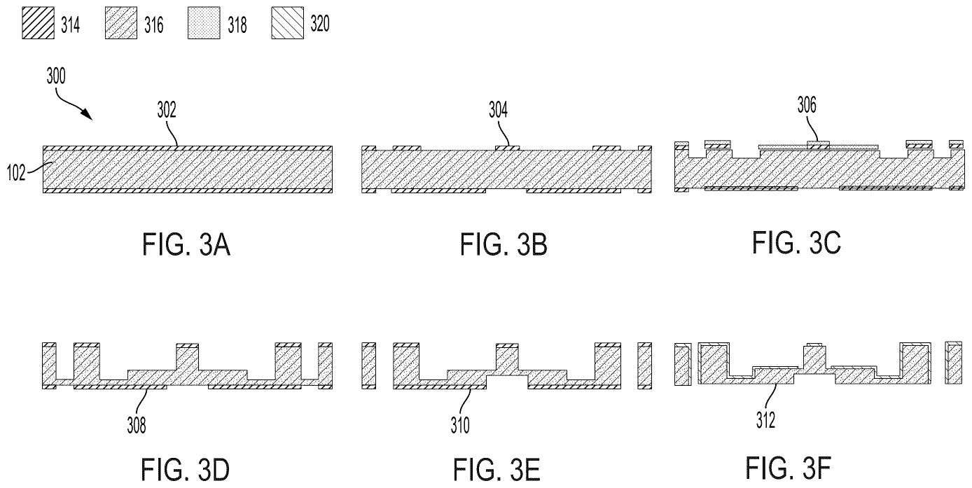

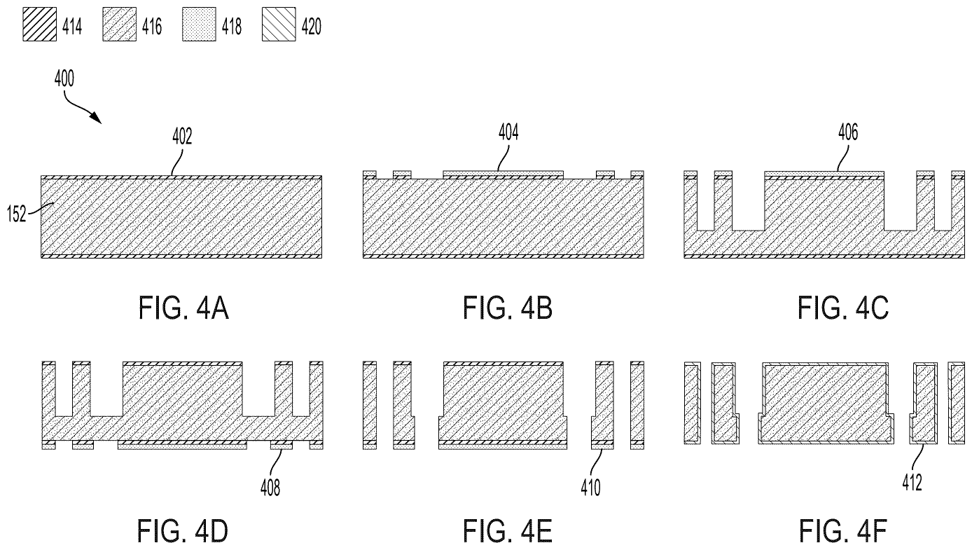

The fabrication process flow for Wafer 1 (i) and Wafer 2 (ii) for this embodiment are shown in FIGS. 3A-3F and FIGS. 4A-4F, respectively.

For Wafer 1, a deep reactive ion etching (DRIE) process may be used to etch a high resistivity silicon (HR-Si) wafer, forming the device's main waveguide channel, narrower EVA channel, and silicon posts on the front side, as depicted in FIGS. 1A-1B. A DRIE process may also used to etch the optical fiber feed holes on the back side of Wafer 1, as well as through silicon via (TSV) holes for connecting standard UG-387/U waveguide flange connectors using both screws (for mechanical connection) and dowel pins (for alignment). Patterned metal may be provided on the sidewalls of the posts.

For Wafer 2, waveguide impedance transformation steps and E-plane 90° bends [3] may be etched within the silicon wafer using DRIE to provide connection between the silicon micromachined EVA waveguide switch and standard waveguide flanges, as depicted in FIG. 2. An additional step in the main waveguide channel's height may be etched in the Wafer 1 around the region of the RF inputs/outputs to improve the transition's performance and bandwidth. Additional steps in height can be added to further improve impedance matching and bandwidth. These multi-step heights in the waveguide channel can be manufactured by patterning and etching the oxide mask for the DRIE to have corresponding steps in height, which are then used to pattern the silicon using successive DRIE and oxide stripping processes. Furthermore, the impedance transformation steps in height can also be etched in Wafer 2, depending upon the design necessity.

A planar magnetron sputtering system may be used to metalize both wafers with 80 nm of chromium and/or titanium for adhesion and 1200 nm of copper for high RF conductivity and with a thickness greater than 3× the skin depth (δₛ) of 358 nm at 85 GHz to reduce ohmic losses. In some embodiments, there may be additional metallization to form an upper layer of >25 nm of gold to prevent oxidation. In some embodiments, metallization may include sputtered chromium and gold (Cr/Au) for gold-gold thermocompression bonding, or sputtered titanium, tungsten, and gold (Ti/W/Au) for gold-gold thermocompression bonding, or metal seed thin film sputtering and electroplated copper or gold to provide a thicker metal layer for greater skin depth coverage at lower frequencies and greater electrical current carrying capacity for higher RF power handling. For example, in some embodiments there may be an adhesion layer (such as Ti) along with a diffusion barrier (such as W), in order to prevent gold from diffusing into the silicon at temperatures that are used for thermocompression bonding. In some other embodiments, to provide an adhesion and diffusion barrier, titanium nitride (TiN) may be sputtered.

FIGS. 3A-3F show a fabrication process flow for the Device Wafer (Wafer 1). FIGS. 4A-4F. Shows a fabrication process flow for the Transition Wafer (Wafer 2).

### 4. Detailed Fabrication Steps

The disclosure provides some embodiments of fabrication process flow steps for the two silicon pieces shown in FIG. 2, the first being the Device Wafer (Wafer 1), and the second being the Transition Wafer (Wafer 2) for this photoconductive solid-state EVA waveguide switch embodiment. The process flows for Wafer 1 and Wafer 2 are shown in FIGS. 3A-3F and FIGS. 4A-4F, respectively.

### 4.1 Device Wafer

FIGS. 3A-3F shows a cross-sectional view of a process flow 300 of manufacturing components of an RF switch, according to some embodiments. While process flow 300 is labeled in FIG. 3A, each of steps 302-312 in FIGS. 3A-3F may be a step of process flow 300. Manufacturing processes described herein such as flow 300 may use materials such as oxide 314, a semiconductor material 316 such as silicon (Si) or high resistivity silicon (HR-Si), a resist 318 such as AZ 1512 photoresist, and one or more metals 320, such as chromium (Cr), copper (Cu) or gold (Au). While materials 314-320 are labeled in FIG. 3A, each of steps 302-312 in FIGS. 3A-3F may use these materials. Referring to FIGS. 3A-3F, the fabrication process of Wafer 1 may begin with substrate 102, which may comprise a double-sided-polished (DSP) high resistivity silicon (HR-Si) wafer. For this embodiment, a 400 μm thick HR-Si wafer with >1 kΩ*cm resistivity and 150 mm diameter is used. The wafer may first be cleaned with piranha solution (3:1, H₂SO₄: H₂O₂) and subsequently rinsed and dried employing a spin-rinse-dryer (SRD) tool. In some embodiments, after this, the wafer is oxidized in an oxidation furnace employing a standard wet oxidation recipe, yielding the desired amount of oxide thickness on both sides of Wafer 1 for subsequent use as a mask for deep reactive ion etching (DRIE). For this embodiment, 1.6 μm of SiO₂ is grown on both sides of the wafer, as shown step 302 in FIG. 3A.

The oxide layer on the front side (FS)—the FS of the substrate is defined as the non-scribed side and the back side (BS) is defined as the scribed side—of the wafer is patterned using a positive photoresist. For this embodiment, photoresist is spread, and then soft baked. Afterward, the photoresist is exposed and developed. For this embodiment, a high-speed direct-write photolithography tool may be used to expose the resist under 405 nm light with an energy density of 160mJ/cm² , and developer may be used to develop the photoresist. To promote wetting, the wafer is cleaned using an oxygen plasma generated in a reactive ion etching (RIE) tool and then immersed in a buffered oxide etch (BOE) bath to pattern the oxide layer. During BOE etch, the BS of the wafer is protected using BOE-resistant tape. The above process is then repeated to pattern the BS oxide layer, as shown in step 304 of FIG. 3B.

A photoresist mask for DRIE is then patterned on the FS of the wafer. For this embodiment, photoresist is used following the spin coating and exposure parameters described in the previous step. Subsequently, DRIE of exposed silicon is performed. For this embodiment, the silicon is etched to a depth of 30 μm using a Bosch process on an inductively coupled plasma reactive ion etching (ICP RIE) tool, as shown in step 306 of FIG. 3C.

After stripping the photoresist, a second FS DRIE is performed, with a depth of 200 μm for this embodiment, as shown in step 308 of FIG. 3D.

Prior to BS DRIE, the wafer is mounted to a 500 μm silicon handle wafer. A 170 μm BS DRIE is performed completing the TSV etch and the optical feed etch in the desired areas. The remaining oxide on both the FS and the BS is stripped by immersing the wafer in BOE, as Patterned metal may then be provided on the sidewalls of the posts, as shown in step 312 of FIG. 3F. The metal may be deposited by sputtering.

### 4.2 Transition Wafer

FIGS. 4A-4F shows a cross-sectional view of a process flow 400 of manufacturing components of an RF switch, according to some embodiments. While process flow 400 is labeled in FIG. 4A, each of steps 402-412 in FIGS. 4A-4F may be a step of process flow 400. Manufacturing processes described herein such as flow 400 may use materials such as oxide 414, a semiconductor material 416 such as silicon (Si) or high resistivity silicon (HR-Si), a resist 418 such as AZ 1512 photoresist, and one or more metals 420, such as chromium (Cr), copper (Cu) or gold (Au). While materials 414-420 are labeled in FIG. 4A, each of steps 402-412 in FIGS. 4A-4F may use these materials. Referring to FIGS. 4A-4F, the fabrication process for Wafer 2 may begin with substrate 152, which may comprise a DSP silicon wafer. This wafer may not need to be HR-Si and may be doped or undoped. The wafer is cleaned, and thermal oxide is grown on both sides like the process described above for Wafer 1 in FIG. 3A. For this embodiment, a 600 μm thick silicon wafer with 150 mm diameter is used, as shown in step 402 of FIG. 4A.

A photoresist is then deposited and developed, and the oxide is patterned on the FS of the wafer like the process described above for Wafer 1 in FIG. 3B. For Wafer 2, the photoresist is left on after the oxide etch to increase the mask thickness for the subsequent DRIE process, as shown in step 404 FIG. 4B.

DRIE of the FS exposed silicon is then performed, like the process for Wafer 1 in FIG. 3C. For this embodiment, the silicon is etched to a depth of 410 μm, as shown in step 406 of FIG. 4C.

After stripping the FS photoresist, another photoresist is deposited and developed on the BS of the wafer, and the BS oxide is patterned like the process described above for Wafer 1 in FIG. 3B. Again, the photoresist is left on to thicken the mask used for the subsequent DRIE process, as shown in step 408 of FIG. 4D.

Prior to BS DRIE, the wafer is mounted to a 500 μm thick silicon handle wafer. DRIE of the BS exposed silicon is then performed, completing the TSV etch in the desired areas. For this embodiment, the silicon is etched to a depth of 190 μm, as shown in step 410 of FIG. 4E.

The remaining photoresist and oxide are stripped, and the wafer is placed in a planar magnetron sputtering system to deposit the metal coating. For Wafer 2, to help with sidewall coverage, the sputtering pressure is set to increase the isotropy of the ejected metal from the target onto the wafer. After metal is deposited onto the FS, the wafer is flipped in the sputtering chamber, and metal is deposited on the BS of the wafer using the same process parameters. For this embodiment, a similar metal layer is deposited as Wafer 1 in FIG. 3F. First, 80 nm of chromium for adhesion, then 1200 nm of copper for 3× the skin depth at 85 GHz, and there may be >25 nm of gold to prevent oxidation, as shown in step 412 of FIG. 4F.

A custom stainless steel metal flange shown in FIG. 2 is laser milled with openings for standard waveguide flange screw holes, alignment dowel pins, and for insertion of optical fibers to control the switch. The standard waveguide flanges are based on dimensions given by IEEE Std 1785.2 standard or UG-387/U type flange connectors.

The custom metal flange is stacked with Wafer 1 and Wafer 2 according to FIG. 2. The pieces are aligned with the dowel pins of the waveguide flange connectors and tightened together using screws and mechanical pressure. The holes for the alignment dowel pins in both the custom metal flange and Wafer 1 and Wafer 2 can be designed with an elliptical alignment hole for increased alignment accuracy to standard waveguide flanges [5].

To improve the quality of the bond between Wafer 1 and Wafer 2, reducing both radiation losses and insertion losses of the switch, thermocompression bonding (TCB) can be used to bond the two wafers before attaching them to the waveguide flanges and custom metal flange using screws. Standard TCB processes for gold-gold and copper-copper (i.e., if the >25 nm of Au is not deposited) are found in the following references [6], [7]. For gold-gold TCB, the temperature of the bond may be kept low to reduce gold diffusion into silicon [6].

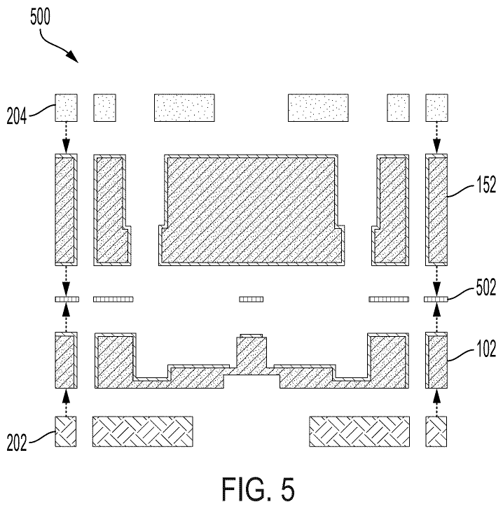

As an alternative to TCB, ultrathin solder preforms with thicknesses on the order of 9 μm, can be used to bond Wafer 1 and Wafer 2. As shown in FIG. 5, the ultrathin solder preform is cut to the required shape and aligned between the two wafers. The stack is placed in a TCB tool to provide a small amount of pressure. The stack is then heated following the required temperature and time process parameters, and the solder preform attaches the two wafers together. This process removes the need for high pressures and temperatures typically required by TCB, improving yield and compatibility of the switch for integration within various semiconductor platforms.

To reduce bonding misalignment between wafers, alignment between Wafer 1 and Wafer 2 can also be achieved using different methods including the following:

First, an alignment wafer in which through hole areas with the dimensions of single device samples diced out of Wafer 1 and Wafer 2 are made using DRIE. The height of the alignment wafer is greater than a single wafer (Wafer 1 or Wafer 2), but less than the combined height of both Wafer 1 and Wafer 2, such that the device samples can be placed in the alignment wafer openings and then bonded. Maximum misalignment between wafers is less than 10 μm.

Second, alignment bump and hole structures can be made on Wafer 1 and Wafer 2, such that the two wafer pieces slot together and are then placed in the bonder. These structures can follow the method shown in [9] with maximum misalignment between wafers less than 4 μm.

Third, in situ alignment in advanced bonding equipment [10]. These tools can reach maximum misalignment between wafers on the order of a single micrometer.

RF switch 500 may be configured similarly as RF switch 2 described above with respect to FIG. 2, except as described herein. FIG. 5 shows cross-section showing the final assembly (exploded view) of the micromachined EVA waveguide switch including an ultrathin solder 502 preform to improve bonding between the device wafer and transition wafer.

### 5. Fabrication Results

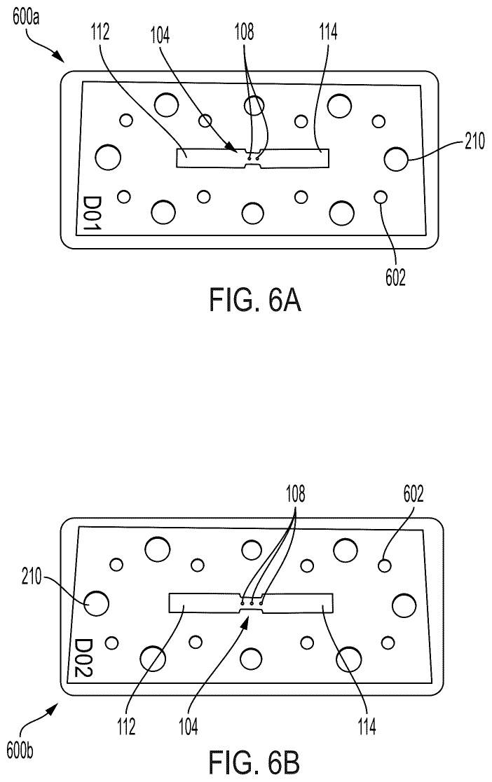

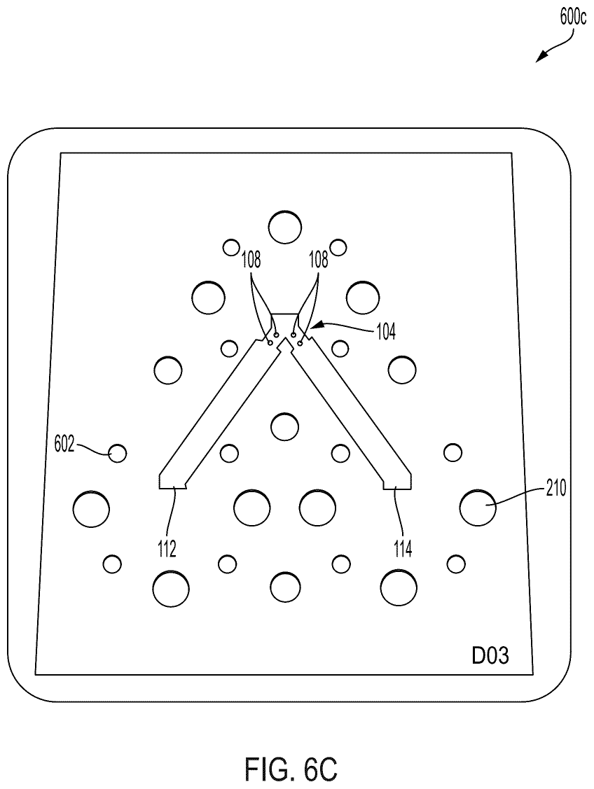

FIGS. 6A-6C show perspective views of components of an RF switch, according to some embodiments. FIGS. 6A-6C show the completed fabrication of the front side of Wafer 1 (Device Wafer) for three different switch embodiments. FIG. 6A shows a two-pole single pole single throw (SPST) EVA waveguide switch 600a with two semiconductor protrusions 108, FIG. 6B shows a three-pole SPST EVA waveguide switch 600b with three semiconductor protrusions 108, and FIG. 6C shows a two-pole single pole double throw (SPDT) EVA waveguide switch 600c with four semiconductor protrusions 108 arranged in two pairs. The larger through holes are used for mechanical bonding of the wafer stack between the waveguide adapters and the custom laser-cut stainless steel flange piece. The smaller through holes are for alignment using the dowel pins that are standard on UG-387/U flange connectors.

FIGS. 6A-6C show illustrations of the completed fabrication of Wafer 1 for a two-pole SPST, a three-pole SPST, and a two-pole SPDT photoconductive solid-state EVA waveguide switch after the metal patterning step in FIG. 3F. The larger through holes 210 may be used with fasteners for mechanical bonding of Wafer 1 and Wafer 2 with the custom laser-cut flange piece and waveguide adapters using screws, while the smaller through holes 602 may be used to align the pieces together using the dowel pins standard on UG-387/U flange connectors.

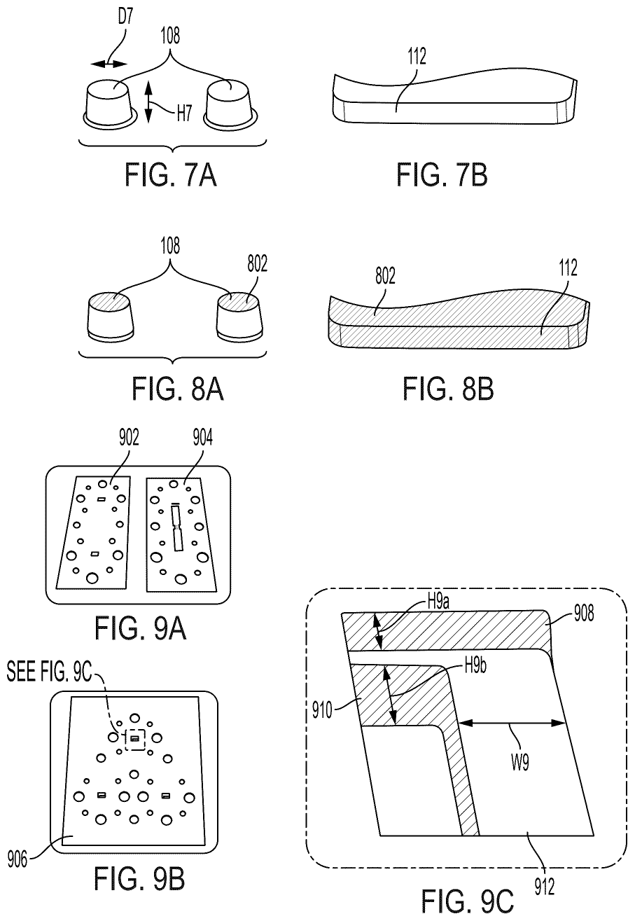

In FIGS. 7A-7B and 8A-8B, illustrations of the metal patterning of the silicon post sidewall are shown. In FIGS. 8A-8B, metal is not provided on the silicon post sidewall in FIG. 8A, with the waveguide sidewall in FIG. 8B completely covered in metal. These results may provide high performance of the switch.

FIGS. 7A-7B show perspective views of components of an RF switch, according to some embodiments. FIGS. 7A-7B shows stereo microscope illustrations. FIG. 7A shows the semiconductor protrusions 108 as silicon posts, and FIG. 7B shows EVA region waveguide sidewall 112, before metal patterning shown in FIG. 3F. The posts may have a diameter D7 of about 240 μm, and a height H7 of about 200 μm.

FIGS. 8A-8B show perspective views of components of an RF switch, according to some embodiments. FIG. 8A shows the semiconductor protrusions 108 as silicon posts, and FIG. 8B shows the waveguide sidewall 112, after metal patterning shown in FIG. 3F. The metal layer 802 is not provided on the silicon post sidewalls, while the waveguide sidewalls are completely coated with the metal layer 802 as may be used for low insertion loss.

FIGS. 9A-9C show perspective views of components of an RF switch, according to some embodiments. According to some embodiments, a completed fabrication of Wafer 2 (Transition Wafer) is shown in FIGS. 9A-9C, with FIG. 9A showing a two-pole SPST EVA waveguide switch 902 (with the corresponding Wafer 1 904 beside), and FIG. 9B showing the two-pole SPDT EVA waveguide switch 906. FIG. 9C shows a close-up of the transition for a particular switch embodiment, with sidewalls 908 formed by an etch of height H9a (e.g., about 300 μm deep), which may be a back side silicon DRIE etch (FIG. 4E with different etch depth), and sidewalls 910 formed by an etch of height H9b (e.g., about 500 μm deep), which may be a front-side silicon DRIE etch (in FIG. 4C with different etch depth), offset from each other by a step surface 912 having a width W9 (e.g., 700 μm) to provide the E-plane 90° bend and impedance matching transition from the waveguide flange into the silicon micromachined waveguide channel.

FIGS. 9A-9C show illustrations of the completed fabrication of Wafer 2 with FIG. 9A showing a two-pole SPST switch, and FIG. 9B showing two-pole SPDT switch. FIG. 9C shows a close-up image of the etched transition region within Wafer 2, demonstrating sufficient metal coverage on the waveguide sidewalls 908 and 910 and inner step surface 912.

The results provided herein demonstrate fabrication of a photoconductive solid-state EVA waveguide switch. Additional processes may further improve the quality of the fabrication and thus the switch's performance, such as by: (1) smoothing the waveguide and post sidewalls by optimizing the silicon DRIE recipe for reduced insertion loss due to rough conductors; and (2) improved coverage of the metals inside the transition features due to the deep etch (upwards of 500 μm for the present embodiments).

With respect to improvement (1), beyond providing an improved the silicon DRIE recipe, another method to improve DRIE sidewall smoothness is to grow a wet thermal oxide approximately 1-2 μm thick. This oxide is grown after the silicon DRIE process and after cleaning the resulting surface polymer from the wafer's surface. The oxide may then be stripped using a BOE solution. The resulting surface may be free of rough edges caused by the scalloping nature of the DRIE process. Furthermore, continuous flow of both etching and polymerization gases in the DRIE process yields smoother sidewalls. In some embodiments, these processes may have poorer selectivity between silicon and the etch mask, which may reduce the overall depth of the etch. An additional method to smooth DRIE sidewalls uses a short timed etch in KOH to selectively etch the sharp features of the scallops, with minimal impact on other features.

With respect to improvement (1), when metalizing large topology etched into silicon, features with large aspect ratios can suffer from shadowing of the mostly directive sputter material from the target to the wafer within a planar magnetron sputtering system, decreasing the metal coverage within the etched region. This can be improved using a more isotropic sputter (higher chamber pressure for) or a sputtering system with angled alignment between the metal target and the wafer. Electroplating the metal after sputtering may also increase thickness, with the additional benefit of improving the electrical current carrying capability of the switch for greater RF power handling.

### 6. Assembly

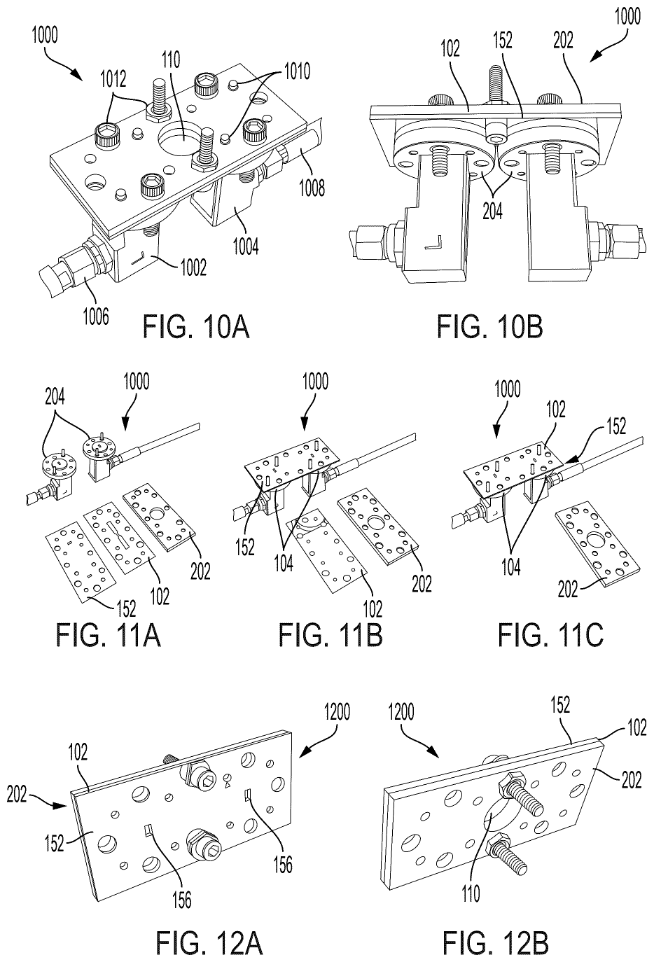

FIGS. 10A-10B show perspective views of an RF switch system 1000, according to some embodiments. FIGS. 10A-10B shows an assembled two-pole SPST photoconductive solid-state EVA waveguide switch according to some embodiments. Alignment is achieved using the dowel pins 1010 standard on UG-387/U waveguide flange 204 may be connectors assemblies including a first connector 1002 coupled to optical fiber 1006, and a second connector 1004 coupled to optical fiber 1008, slotted into the smaller through holes etched using DRIE into both Wafer 1 and Wafer 2, and laser cut into the custom stainless steel flange 202. An opening in the custom flange piece allows access to the back side of Wafer 1 to insert optical fibers for control of the switch at aperture 110. Fasteners 1012 couple the stack of components together.

FIGS. 10A-10B shows illustrations of an assembled silicon micromachined photoconductive solid-state EVA waveguide switch embodiment. FIG. 10A shows a top isometric view showing the fiber access area in the custom laser cut stainless steel flange piece, and FIG. 10B shows a bottom side view showing the mechanically stacked arrangement of semiconductor substrate 102 (Wafer 1, Device Wafer) and semiconductor substrate 152 (Wafer 2, Transition Wafer) along with the custom flange 202 connected with screws to standard waveguide flanges 204 provide by coax-to-waveguide adapters for measurement and characterization purposes. For this embodiment, the design included 2× holes for optical fibers on the back side to produce a two-pole SPST photoconductive solid-state EVA waveguide switch for operation in the W-band (75-110 GHz). The dowel pins of the waveguide flanges are used for alignment of the silicon wafer pieces (Wafer 1 and Wafer 2) to the waveguide flanges.

FIGS. 11A-11C show perspective views of a process of assembling an RF switch system, according to some embodiments. FIGS. 11A-11C shows the assembly of the switch described above. Semiconductor substrate 152 (Wafer 2, Transition Wafer) is first placed onto the waveguide adapters flanges 204 through the dowel pins located on the adapter flanges. Semiconductor substrate 102 (Wafer 1, Device Wafer) is then placed on top of semiconductor substrate 152, again using the dowel pins, aligning both substrates2 to each other and the waveguide openings in the adapters. Finally, the laser-cut flange 202 is placed on top, and screws are inserted through the larger holes to mechanically bond the wafers together, as shown in FIG. 11B. As noted earlier, the switch component itself starts at Wafer 2, the transition wafer. The waveguide adapters may be primarily used for characterization purposes and are not part of the switch.

FIG. 11A-11B show illustrations of the assembly of the two-pole SPST photoconductive solid-state EVA waveguide switch. FIG. 11A shows an illustration before assembly, FIG. 11B shows Wafer 2 placed on the waveguide adapters and aligned using dowel pins, and FIG. 11C shows Wafer 1 placed on top of Wafer 2.

FIGS. 12A-12B show perspective views of an RF switch system 1000, according to some embodiments. FIGS. 12A-12B show illustrations of the switch component by itself, with FIG. 12A showing the switches front-side showing the waveguide transitions, and FIG. 12B showing back side showing the access to the fiber holes for optical excitation of the silicon posts. The overall dimensions of the switch component are to allow connection to standard UG-387/U waveguide flanges.

FIGS. 12A-12B show the front side and back side of the EVA waveguide switch component by itself, respectively, without the waveguide adapters connected. The switch can be made even more compact by using an inline approach, i.e., having the transitions on opposite sides of the sample (one transition on the front side and one transition on the back side), making the switch only as wide as a single standard UG-387/U flange (20.1 mm by 20.1 mm). See Section 8 for more details. The approach presented here was chosen for ease of demonstration of the minimal viable product.

The switching device itself (including only the EVA region and silicon posts, shown in FIG. 7A) is only 2.54 mm by 3.02 mm for the two-pole SPST, 2.54 mm by 4.26 mm for the three-pole SPST, and 1.40 mm by 5.72 mm for the two-pole SPDT. It is clear the transitions take up most of the total area of the complete switch component shown in FIGS. 12A-12B. This is necessary to connect the switch to standard waveguide flanges. The switching device by itself can be inserted into even smaller form factors when integrated with certain semiconductor processes, such as CMOS.

### 7. Embodiment With Increased On/Off Switching Speed

The switching speed of photoconductive switches may be strongly influenced by the generation and recombination rate of the free-carriers (electron-hole pairs) generated within the semiconductor by optical excitation [11, 12]. Photoconductive solid-state EVA waveguide switches comprise a shunt type switch, such that when the semiconductor post is not excited by light, the switch is in its ON (dark) state, and when the semiconductor post is excited by light, the switch is in its OFF (photoconductive) state. The length of time for the switch to transition between these two states is called the switching speed, or switching time, where the dark-to-photoconductive transition time is the ON-to-OFF time, and the photoconductive-to-dark transition is the OFF-to-ON time of the switch. These two times are important parameters to consider in the choice of a switch for high-speed applications, providing valuable performance metrics such as the modulation rate of the switch.

In typical environments, the generation rate of semiconductors is orders of magnitude faster than the recombination rate, which is inversely proportional to the carrier lifetime of the semiconductor [12]. Not considering diffusion, the carrier lifetime of the semiconductor may be the rate limiting factor that is typically considered first to increase the speed of the switch. Both the ON-to-OFF and the OFF-to-ON time of the switch may be functions of the carrier lifetime. Thus, by decreasing the carrier lifetime, the switching speed can be increased.

The main switching element of the photoconductive solid-state EVA waveguide switch is a semiconductor volume excited by photons which are absorbed and generate electron-hole pairs within the volume. One way to decrease the carrier lifetime of a semiconductor volume is to increase its total surface area. Increasing surface area has two important impacts. First, an increase in the surface area of the semiconductor increases the number of surface recombination centers available to annihilate photo-excited electron-hole pairs, decreasing the carrier lifetime. Second, keeping the total volume fixed and increasing the surface area of the semiconductor creates thinner semiconductor regions. This achieves a higher effective photoconductivity of the semiconductor since the need for absorption of the photons deep within the volume and diffusion of the generated free-carriers throughout is relaxed. Importantly, this enables the use of alternative semiconductor platforms with faster free-carrier mobilities than silicon such as gallium arsenide (GaAs). In some embodiments, various semiconductor materials may be used in the systems described herein, such as materials comprising silicon, germanium, silicon germanium (SiGe), gallium arsenide (GaAs), and/or other III-V semiconductor materials (e.g., semiconductor materials comprising gallium or indium). GaAs and other III-V semiconductors may have faster recombination and optical photon absorption rates than silicon, and may typically require large optical powers to penetrate the semiconductor material and generate thick enough photoconductive regions for use in microwave and millimeter-wave systems [13]. The use of GaAs versus silicon as the based semiconductor of the switch may increase the switching speed by two or three orders of magnitude. The thinner regions also promote carrier confinement, further increasing the switching speed [11, 14].

Modifying the process flow in FIGS. 3A-3F, the silicon (or other semiconductor) post of the photoconductive solid-state EVA waveguide switch can be fabricated with greater surface area to increase the switching speed of the photoactive area. This may be accomplished by a back side etch into the silicon post, perforating the post with smaller trenches or openings, increasing its total surface area. While this may decrease the effective permittivity of the semiconductor post operating as a shunt dielectric capacitor element of the LC resonator in the switch's ON state, this may be compensated in the RF design stage of the switch.

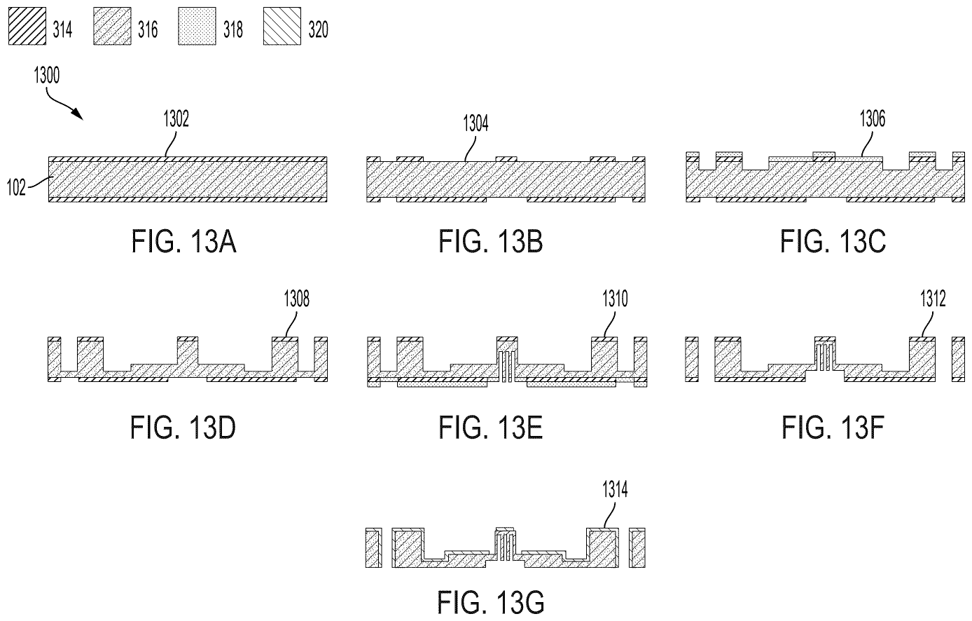

FIG. 13A-13G shows a cross-sectional view of a process flow 1300 of manufacturing components of an RF switch, according to some embodiments. While process flow 1300 is labeled in FIG. 13A, each of steps 1302-1314 in FIGS. 13A-13F may be a step of process flow 1300. While materials 314-320 are labeled in FIG. 13A, each of steps 1302-1314 in FIGS. 13A-13F may use these materials. FIGS. 13A-13G show a further process flow for a Device Wafer (Wafer 3) with increased switching speed using substrate 102. At step 1310 of FIG. 13E, an extra back side DRIE is performed within the post structure to increase its surface area. The remaining steps may be the same as described with respect to FIGS. 3A-3F. For example, steps 1302-1308 may be similar to steps 302-308 and steps 1312-1314 may be similar to steps 310-312. FIGS. 13A-13G show a fabrication process flow for a Device Wafer (Wafer 3) incorporating a back side post etch for faster switching speed. In the fabrication process step of FIG. 13G, the metal may be patterned according to various metal patterning techniques.

FIG. 14, described in more detail above, shows an exploded cross-sectional view of an RF switch, according to some embodiments. In FIG. 14, the cross-section and assembly of the switch 1400 is shown, again demonstrating minimal change in the overall fabrication and assembly of the switch, while incorporating advanced performance compared to previous embodiments. FIG. 14 shows a cross-section showing the final assembly (exploded view) of the micromachined EVA waveguide switch incorporating the back side post etch for faster switching speed with an updated Device Wafer (Wafer 3).

### 8. Embodiment With Inline Axial Waveguide Flange Input/Output Ports

The switch embodiments provided above describe a single-sided approach to connect standard waveguide flanges to the silicon wafer stack. A reason for this approach may be to allow easy access to the back side of Wafer 1 (Device Wafer) for optical fiber insertion and switch control. The single-sided approach may use long waveguide interconnects between the flange connection and the switch component due to the size of the waveguide flange, as discussed in Section 6. This may increase the total insertion loss of the switch component measured from waveguide flange to waveguide flange.

An alternative to the single-sided approach is to connect the switch to standard waveguide flanges using an inline approach with axial waveguide ports. This may reduce the length of waveguide interconnect between the flange and the switch component, which may significantly reduce the overall switch component's waveguide flange to waveguide flange insertion loss.

FIG. 15 shows an exploded cross-sectional view of an RF switch, according to some embodiments. FIG. 15 illustrates a cross-section assembly of a switch 1500 with inline axial waveguide ports. As shown in FIG. 15, partial flanges 1506a and 1506b may couple with the input/outputs described above, but differ in that the two input/outputs are located on opposite sides of the substrate stack. To accommodate this arrangement, the semiconductor substrate 1502 may be modified from semiconductor substrate 102 to have ports on top and bottom.

Similarly, the switch 1500 may include two semiconductor substrates 1504a and 1504b as transition wafers for the top and bottom of semiconductor substrate 1502.

Flange 1 and Flange 2 are not specifically shown inline in FIG. 15 for the sake of incorporating the optics feed in the illustration. However, Flange 1 and Flange 2 can easily be made inline in the actual realized device by incorporating H-plane bends in the Device Wafer (Wafer 4). The process flow shown in FIGS. 3A-3F for the previous Device Wafer (Wafer 1) may be modified to allow for an opening in the bottom broadside wall for connection to an additional Transition Wafer (Wafer 6) below. Furthermore, the additional etched area in the right side of Transition Wafer (Wafer 5) can be added to allow the extra step for impedance matching the Transition Wafer (Wafer 6) RF input/output connection from Flange 2.

FIG. 15 shows a cross-section showing the final assembly (exploded view) of the micromachined EVA waveguide switch incorporating an inline connection with standard waveguide flanges with modifications to the transition wafers (Wafer 5 and Wafer 6), and device wafer (Wafer 4).

### 9. Further Variations

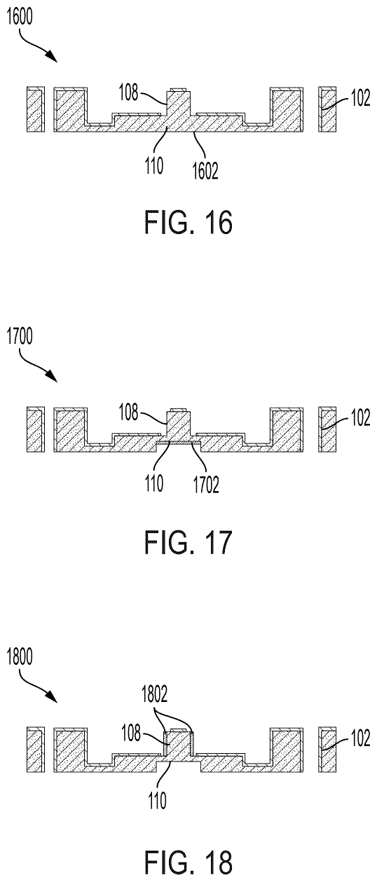

FIG. 16 shows a perspective view of components of an RF switch, according to some embodiments. FIG. 16 shows components 1600 of an RF switch with a modified semiconductor substrate 102. As shown in FIG. 16, the semiconductor substrate 102 may include a surface 1602 rather than an aperture 110 for the semiconductor protrusion 108, which may may be flat relative to the semiconductor substrate 102. The surface 1602 may provide for improved thermocompression bonding of the semiconductor protrusion 108 to the transition wafer. Using a flat surface may provide for the force from the thermocompression bonding to apply more directly through the semiconductor protrusion 108 and the transition wafer yielding a better metal-to-metal bond between the metal on the top of the semiconductor protrusion 108 to the transition wafer.

FIG. 17 shows a cross-sectional view of components of an RF switch, according to some embodiments. FIG. 17 shows components 1700 of an RF switch with a modified semiconductor substrate 102. As shown in FIG. 17, the semiconductor substrate 102 may include a layer 1702 in the an aperture 110 for the semiconductor protrusion 108. Layer 1702 may comprise an anti-reflective coating. The coating may be configured to improve the efficiency of particles (e.g., photons) entering into the semiconductor protrusion 108 through the air-semiconductor (e.g., air-silicon) interface at different angles from the EMR source Additionally, when the semiconductor substrate 102 may include a surface 1602 rather than an aperture 110 (as described with respect to FIG. 16) , the layer 1702 may be provided on the surface 1602 rather than in the aperture.

FIG. 18 shows a cross-sectional view of components of an RF switch, according to some embodiments. FIG. 18 shows components 1800 of an RF switch with a modified semiconductor substrate 102. As shown in FIG. 16, the semiconductor substrate 102 may include a layer 1802 disposed on the sides of the semiconductor protrusion 108. The layer 1802 may be formed or deposited on the wall. In some embodiments, the layer may be a reflective layer. The reflective layer may be disposed only on a waveguide channel side of the silicon post to reflect back any particles (e.g., photons) that are not absorbed in the semiconductor (e.g., silicon).

### 10. System Arrangements

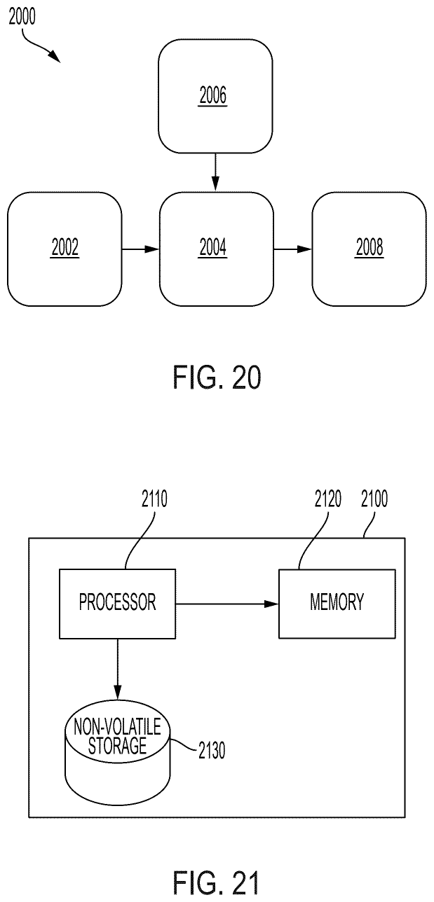

FIG. 20 shows a schematic block diagram of an RF switch system, according to some embodiments. The RF switch system 2000 illustrated in FIG. 20 may include a RF switch 2004, first signal input/output 2002, and second signal input/output 2008, and a controller 2006. The RF switch may comprise any of the RF switches described herein, for example, switch 100, 200, 500, 1400, or 1500, and/or may incorporate features and components of other embodiments described herein. The first signal input/output 2002 and second signal input/output 2008 may comprise RF connectors and/or optical cables for transmitting signals described herein. The controller 2006 may comprise an EMR source and/or appropriate controlling hardware and/or software of modulating the EMR source. The controller 2006 may control EMR supplied to a semiconductor protrusion of the RF switch 2004, thereby controlling transmission of signals through a waveguide channel of the RF switch 2004, and between the first signal input/output 2002 and second signal input/output 2008.

An illustrative implementation of a computer system 2100 that may be used in connection with any of the embodiments of the disclosure provided herein is shown in FIG. 21. The computer system 2100 may include one or more processors 2110 and one or more articles of manufacture that comprise non-transitory computer-readable storage media (e.g., memory 2120 and one or more non-volatile storage media 2130). The processor 2110 may control writing data to and reading data from the memory 2120 and the non-volatile storage device 2130 in any suitable manner. To perform any of the functionality described herein, the processor 2110 may execute one or more processor-executable instructions stored in one or more non-transitory computer-readable storage media (e.g., the memory 2120), which may serve as non-transitory computer-readable storage media storing processor-executable instructions for execution by the processor 2110.

The terms “program” or “software” are used herein in a generic sense to refer to any type of computer code or set of processor-executable instructions that can be employed to program a computer or other processor to implement various aspects of embodiments as discussed above. Additionally, it should be appreciated that according to one aspect, one or more computer programs that when executed perform methods of the disclosure provided herein need not reside on a single computer or processor but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in one or more non-transitory computer-readable storage media in any suitable form. For simplicity of illustration, data structures may be shown to have fields that are related through location in the data structure. Such relationships may likewise be achieved by assigning storage for the fields with locations in a non-transitory computer-readable medium that convey relationship between the fields. However, any suitable mechanism may be used to establish relationships among information in fields of a data structure, including through the use of pointers, tags or other mechanisms that establish relationships among data elements.

### 11. INCORPORATION BY REFERENCE

The following are hereby incorporated by reference herein:

To the extent that the references incorporated herein use terminology or definitions conflicting with those in the present document, then the present document controls.
[1] T. R. Jones, A. Fisher, D. W. Barlage, and D. Peroulis, “A photogenerated silicon plasma waveguide switch and variable attenuator for millimeter-wave applications,” IEEE Transactions on Microwave Theory and Techniques, vol. 69, no. 12, pp. 5393-5403, December 2021.
[2] T. R. Jones, A. Fisher, D. W. Barlage, and D. Peroulis, “A W-band photoconductive evanescent-mode waveguide switch,” in IEEE/MTT-S International Microwave Symposium, Denver, CO, USA, June 2022, pp. 959-962.
[3] E. T. Der, T. R. Jones, A. Fisher, M. D. Sinanis, K. Moez, D. W. Barlage, and D. Peroulis, “A W-band SPDT photoconductive evanescent-mode waveguide switch,” IEEE Microwave and Wireless Technology Letters, vol. 33, no. 6, pp. 831-834, June 2023.
[4] Zhao, X., Glubokov, O., and Oberhammer, J., “A silicon-micromachined waveguide platform with axial ports for integrated sub-THz filters,” IEEE Transactions on Microwave Theory and Techniques, vol. 70, no. 2, 1221-1232, February 2022.
[5] J. Campion, U. Shah, and J. Oberhammer, “Elliptical alignment holes enabling accurate direct assembly of microchips to standard waveguide flanges at sub-THz frequencies,” in IEEE MTT-S International Microwave Symposium, Honolulu, HI, USA, June 2017, pp. 1262-1265.
[6] D. Back, K. P. Drummond, M. D. Sinanis, J. A. Weibel, S. V. Garimella, D. Peroulis, and D. B. Janes, “Design, fabrication, and characterization of a compact hierarchical manifold microchannel heat sink array for two-phase cooling,” IEEE Transactions on Components, Packaging and Manufacturing Technology, vol. 9, no. 7, pp. 1291-1300, July 2019.
[7] A. K. Panigrahy, and K. N. Chen, “Low temperature Cu—Cu bonding technology in three-dimensional integration: an extensive review,” Journal of Electronic Packaging, Transactions of the ASME, vol. 140, no. 1, pp. 1-11, March 2018.
[8] Indium Corporation AuLTRA ThInFORMS Gold Preforms. Accessed: Sep. 3, 2023. [Online]. Available: https://www.indium.com/products/solders/gold/gold-preforms/
[9] O. Glubokov, X. Zhao, J. Campion, B. Beuerle, U. Shah, and J. Oberhammer, “Investigation of fabrication accuracy and repeatability of high-Q silicon-micromachined narrowband sub-THz waveguide filters,” IEEE Transactions on Microwave Theory and Techniques, vol. 67, no. 9, pp. 3696-3706. September 2019.
[10] Applied Microengineering Ltd. Accessed: Sep. 3, 2023. [Online]. Available: https://aml.co.uk/awb-aligner-wafer-bonder/
[11] A. Fisher, T. R. Jones, and D. Peroulis, “Design and optimization of a high-power solid-state plasma RF switch,” IEEE Transactions on Microwave Theory and Techniques, accepted for publication on Jun. 20, 2023.
[12] S. M. Sze, Semiconductor Devices: Physics and Technology, 2nd ed. New York, NY, USA: Wiley, 2022.
[13] A. Kannegulla, Md. I. Bin Shams, L. Liu, and L.-J. Cheng, “Photo-induced spatial modulation of THz waves: opportunities and limitations,” Optics Express, vol. 23, no. 25, pp. 32098-32112, December 2015.
[14] E. Gaubas and J. Vanhellemont, “Comparative study of carrier lifetime dependence on dopant concentration in silicon germanium,” Journal of the Electrochemical Society, vol. 154, no. 3, pp. H231, 2007.

To the extent the incorporated documents provide or include definitions for terms appearing in the present disclosure and those definitions conflict with the usage of such terms herein, the present disclosure controls.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within ±10% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

What is claimed is:

1. A radio frequency (RF) switch integrated with a semiconductor substrate, the RF switch comprising:
a waveguide channel disposed in the semiconductor substrate, the waveguide channel comprising at least one internal wall;
a semiconductor protrusion extending from the at least one internal wall into the waveguide channel, wherein the semiconductor protrusion comprises a surface configured to receive electromagnetic radiation (EMR); and
at least one trench extending into the surface of the semiconductor protrusion.

2. The RF switch of claim 1, wherein:
the semiconductor protrusion is configured to receive, in the at least one trench, the EMR from an EMR emitter coupled to the surface; and
responsive to receiving the EMR, the semiconductor protrusion is configured to impede RF signals in the waveguide channel.

3. The RF switch of claim 2, wherein:
the at least one internal wall is formed of the semiconductor substrate; and
the waveguide channel comprises:
a metallic layer formed on the at least one internal wall; and
at least one port configured to transmit RF signals into and/or out of the waveguide channel.

4. The RF switch of claim 2, wherein the EMR emitter comprises a laser diode, a vertical-cavity-surface-emitting laser (VCSEL), a light emitting diode (LED), or an optical fiber.

5. The RF switch of claim 1, further comprising:
an anti-reflective layer disposed on the surface.

6. The RF switch of claim 1, further comprising:
a reflective layer disposed on at least a portion of the semiconductor protrusion.

7. The RF switch of claim 1, further comprising:
an aperture exposing the surface of the semiconductor protrusion.

8. The RF switch of claim 7, wherein:
the aperture has a first etch depth; and
the at least one trench has a second etch depth.

9. The RF switch of claim 1, wherein:
the semiconductor protrusion comprises a first end and a second end opposite the first end;
the first end of the semiconductor protrusion extends into the waveguide channel; and
the at least one trench extends into the surface of the semiconductor substrate at the second end of the semiconductor protrusion.

10. The RF switch of claim 1, wherein the RF switch comprises a plurality of semiconductor protrusions extending from the at least one internal wall into the waveguide channel.

11. A radio frequency (RF) switch integrated with a semiconductor substrate, the RF switch comprising:
a waveguide channel disposed in the semiconductor substrate;
a discrete semiconductor obstacle disposed in the waveguide channel, wherein the discrete semiconductor obstacle comprises a surface configured to receive electromagnetic radiation (EMR); and
at least one trench extending into the surface of the discrete semiconductor obstacle.

12. The RF switch of claim 11, wherein:
the discrete semiconductor obstacle is configured to receive, in the at least one trench, the EMR from an EMR emitter coupled to the surface; and
responsive to receiving the EMR, the discrete semiconductor obstacle is configured to impede RF signals in the waveguide channel.

13. The RF switch of claim 11, wherein:
the waveguide channel comprises:
at least one internal wall;
a metallic layer formed on the at least one internal wall; and
at least one port configured to transmit RF signals into and/or out of the waveguide channel.

14. The RF switch of claim 11, wherein the discrete semiconductor obstacle comprises silicon.

15. The RF switch of claim 11, wherein the discrete semiconductor obstacle comprises a III-V semiconductor material.

16. The RF switch of claim 11, wherein the discrete semiconductor obstacle comprises germanium and/or silicon germanium.

17. The RF switch of claim 11, wherein the at least one trench comprises a plurality of trenches.

18. A radio frequency (RF) switch integrated with a semiconductor substrate, the RF switch comprising:
a first port arranged in the semiconductor substrate;
a second port arranged in the semiconductor substrate; and
means for selectively impeding transmission of RF signals between the first port and the second port, the means comprising at least one trench.

19. The RF switch of claim 18, further comprising:
a waveguide channel extending between the first port and the second port,
wherein the means is arranged in the waveguide channel.

20. The RF switch of claim 18, wherein:
the means is configured to, responsive to receiving EMR at the trench, impede RF signals between the first port and the second port.
